(19) United States
(12) Patent Application Publication
(10) Pub. No.: US 2021/0233899 A1
(43) Pub. Date: Jul. 29, 2021

(54) DISPLAY PANEL, MANUFACTURING METHOD OF SAME, AND TILED DISPLAY PANEL

(71) Applicant: Shenzhen China Star Optoelectronics Semiconductor Display Technology Co,. Ltd., Shenzhen, Guangdong (CN)

(72) Inventor: Macai LU, Shenzhen (CN)

(73) Assignee: Shenzhen China Star Optoelectronics Semiconductor Display Technology Co,. Ltd., Shenzhen,Guangdong (CN)

(21) Appl. No.: 16/625,731

(22) PCT Filed: Nov. 21, 2019
(86) PCT No.: PCT/CN2019/120042

§ 371 Date: Dec. 22, 2019

(30) Foreign Application Priority Data
Nov. 4, 2019 (CN) 201911064368.3

(51) Int. Cl. H01L 25/16; H01L 27/12; H01L 23/48

(52) U.S. Cl. CPC H01L 25/167; H01L 27/1259; H01L 23/481; H01L 27/124

(57) ABSTRACT

A display panel comprises a plurality of light-emitting components, an array substrate, and a driver chip. The array substrate comprises: a base substrate; a plurality of signal lines disposed on a first surface of the base substrate; and a fanout circuit disposed on a second surface of the base substrate; the driver chip is disposed on a second surface side, and is electrically connected to the fanout circuit; a plurality of openings are provided on the array substrate, the plurality of openings are located on an edge of the array substrate and penetrate the array substrate, the array substrate comprises a plurality of electrical connection parts, and the plurality of electrical connection parts are electrically connected to the plurality of signal lines and the fanout circuit.

### BACKGROUND OF INVENTION

### Field of Invention

The present disclosure relates to the display field, and particularly relates to a display panel, a manufacturing method of same, and a tiled display panel.

### Description of Prior Art

In the display field, bezel-free displays or narrow-bezel displays gradually become mainstream. As for displays, such as liquid crystal displays (LCDs), organic light-emitting diode displays (OLEDs), and light emitting diode displays (LEDs), the larger the screen size, the higher the manufacturing difficulty and the manufacturing cost per unit area. Therefore, large-size displays are usually formed by tiling a plurality of small or medium-sized displays. The existence of bezels of the small or medium-sized displays will lead to presence of bar shaped seams in display areas of tiled display panels, thus lowering display quality.

In view of this, the present disclosure aims to provide a bezel-free or narrow-bezel display panel and a manufacturing method of the same. Besides, the present disclosure also provides a tiled display panel which can eliminate or reduce seams.

### SUMMARY OF INVENTION

A display panel, comprises a plurality of light-emitting components, an array substrate, and a driver chip, wherein the plurality of light-emitting components are electrically connected to a side of the array substrate, and the driver chip is electrically connected to another side of the array substrate, and

the array substrate comprises:

a transparent substrate comprises a first surface and a second surface disposed opposite to the first surface;

a plurality of signal lines disposed on the first surface of the base substrate; and

a fanout circuit disposed on the second surface of the base substrate, and the fanout circuit is electrically connected to the plurality of signal lines;

wherein the driver chip is disposed on the second surface of the base substrate, and the driver chip is electrically connected to the fanout circuit; and

a plurality of openings are provided on the array substrate, wherein the plurality of openings are located on an edge of the array substrate and penetrate the array substrate, the array substrate comprises a plurality of electrical connection parts, and the plurality of electrical connection parts are electrically connected to the plurality of signal lines and the fanout circuit.

In a display panel of the present disclosure, the opening are defined as grooves provided on a sidewall of the array substrate.

In a display panel of the present disclosure, the opening are defined as through-holes penetrating the array substrate.

In a display panel of the present disclosure, a recess is provided on a sidewall of the array substrate inside the openings, the electrical connection parts comprise an electrical connection convex, the signal lines are exposed by the recess, and the electrical connection convex contacts with the signal lines.

In a display panel of the present disclosure, the plurality of openings comprise a plurality of first openings arranged in a first direction, the plurality of electrical connection parts comprise a plurality of first electrical connection parts disposed in the plurality of first openings, the plurality of signal lines comprise a plurality of gate lines and each of the first electrical connection parts is electrically connected to one of the gate lines.

In a display panel of the present disclosure, the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

In a display panel of the present disclosure, the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, and each of the first electrical connection parts is electrically connected to one of the gate lines, the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

In a display panel of the present disclosure, the light-emitting components are defined as a micro light-emitting diode or an organic light-emitting diode.

A manufacturing method of a display panel, comprises steps of:

a fanout circuit forming step of providing a first substrate, wherein the first substrate comprises a base substrate and a plurality of signal lines, the base substrate comprises a first surface and a second surface disposed opposite to the first surface, the plurality of signal lines are disposed on the first surface of the base substrate, and forming a fanout circuit on the second surface;

an opening forming step of providing a plurality of openings on an edge of the base substrate, wherein the plurality of openings penetrate the middle substrate, the first end connects with the fanout circuit, and the second end connects with the signal lines;

an electrical connection part forming step of forming the electrical connection part in the openings, the electrical connection part is electrically connected to the signal line and the fanout circuit, and the array substrate is obtained;

a bonding step of bonding a driver chip on the fanout circuit; and

a light-emitting component forming step of electrically connecting a plurality of light-emitting components on the array substrate.

In a manufacturing method of the display panel of the present disclosure, the step of providing the plurality of openings on an edge of the base substrate comprises a step of forming a plurality of recesses on a sidewall of the base substrate or providing the plurality of openings in the base substrate.

In a manufacturing method of the display panel of the present disclosure,

the electrical connection part forming step comprises the steps of:

etching a side wall inside the openings to expose the signal lines,

and forming a metal layer in the openings to form the electrical connection part.

a tiled display panel formed by tiling a plurality of display panels,

wherein the display panel comprises a plurality of light-emitting components, an array substrate, and a driver chip, wherein the plurality of light-emitting components are electrically connected to a side of the array substrate, and the driver chip is electrically connected to another side of the array substrate, and

the array substrate comprises:

a transparent substrate comprising a first surface and a second surface disposed opposite to the first surface;

a plurality of signal lines disposed on the first surface of the base substrate; and

a fanout circuit disposed on the second surface of the base substrate, and is electrically connected to the plurality of signal lines;

wherein the driver chip is disposed on the second surface of the base substrate, and are electrically connected to the fanout circuit; and

a plurality of openings are provided on the array substrate, wherein the plurality of openings are located on an edge of the array substrate and penetrate the array substrate, and the array substrate comprises a plurality of electrical connection parts, the plurality of electrical connection parts are electrically connected to the plurality of signal lines and the fanout circuit.

In a tiled display panel of the present disclosure, the openings are defined as grooves provided on a sidewall of the array substrate.

In a tiled display panel of the present disclosure, the openings are defined as through-holes penetrating the array substrate.

In a tiled display panel of the present disclosure, a recess is provided on a sidewall of the array substrate inside the openings, the electrical connection parts comprise an electrical connection convex, the signal lines are exposed by the recess, and the electrical connection convex contacts with the signal lines.

In a tiled display panel of the present disclosure, the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, each of the first electrical connection parts is electrically connected to one of the gate lines.

In a tiled display panel of the present disclosure, the plurality of openings comprises a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection part is electrically connected to one of the source/drain lines.

18. The tiled display panel of claim 12, wherein the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, each of the first electrical connection parts is electrically connected to one of the gate lines, the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

In a tiled display panel of the present disclosure, the light-emitting components are defined as a micro light-emitting diode or an organic light-emitting diode.

The fanout circuit and the driver chip of the display panel of the present disclosure are disposed at a backside of the array substrate. By providing the openings on the edge of the array substrate and forming the electrical connection parts in the openings to electrically connect the driver chip, the fanout circuit, and the TFT layer, a display area becomes closer to a bezel area, so as to achieve an effect of bezel-free or narrow-bezel.

The above-mentioned bezel-free display panels or narrow-bezel display panels are applied in the tiled display panel of the present disclosure, so that seams can be narrowed to a size of one-pixel unit, so as to make the seams difficult to be recognized by the naked eye by users and achieve an effect of eliminating or reducing seams.

### BRIEF DESCRIPTION OF DRAWINGS

In order to more clearly illustrate the technical solution of the present invention, a brief description of the drawings that are necessary for the illustration of the embodiments will be given as follows. Obviously, the drawings described below show only some embodiments of the present invention, and a person having ordinary skill in the art may also obtain other drawings based on the drawings described without making any creative effort.

FIG. 1 is a front view of a display panel according to one embodiment of the present disclosure.

FIG. 2 is an isometric view of the display panel of FIG. 1.

FIG. 3 is a cross-sectional view of the display panel of FIG. 1 along A-A line.

FIG. 4 is a cross-sectional view of the display panel of FIG. 1 along the B-B line.

FIG. 5 is an isometric view of a display panel according to another embodiment of the present disclosure.

FIG. 6(a) to FIG. 6(k) is a schematic view of a manufacturing method of a display panel according to one embodiment of the present disclosure along the A-A line.

FIG. 7 is a front view of a tiled display panel according to one embodiment of the present disclosure.

### DETAILED DESCRIPTION OF PREFERRED EMBODIMENTS

The present disclosure is further described in detail below with reference to the accompanying drawings and embodiments. Obviously, the following described embodiments are only part of the present disclosure but not all. A person having ordinary skill in the art may obtain other embodiments based on the embodiments provided in the present disclosure without making any creative effort, which all belong to the scope of the present disclosure.

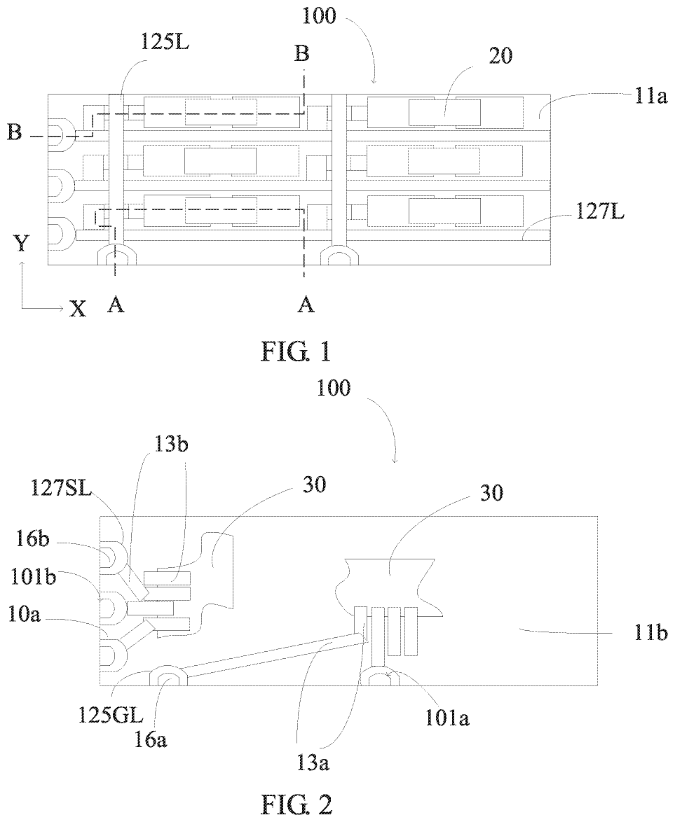

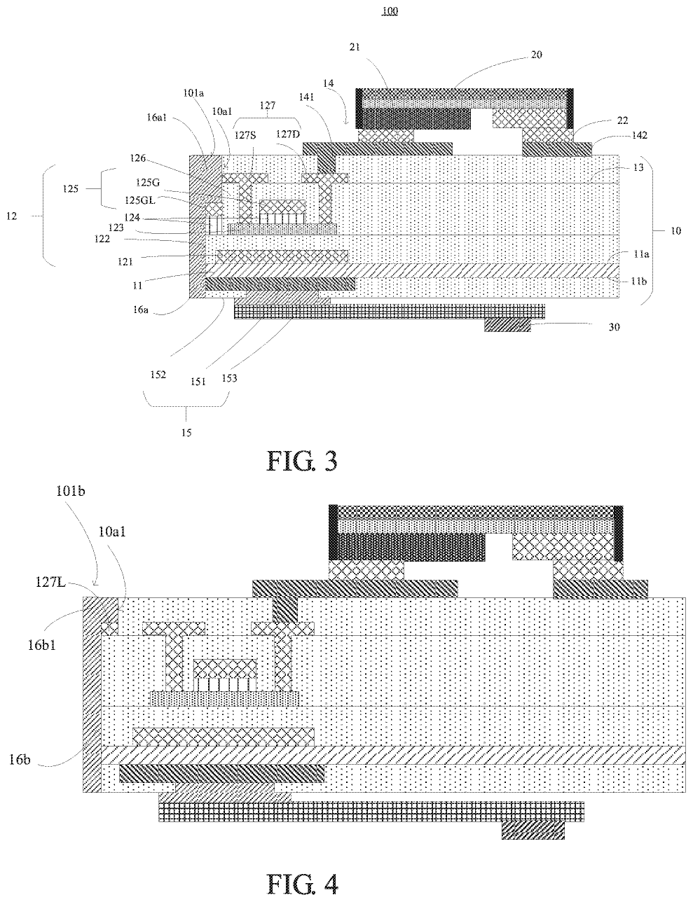

Please refer to FIG. 1 to FIG. 4, a display panel 100 according to one embodiment of the present disclosure comprises an array substrate 10, a plurality of light-emitting components 20, and a driver chip 30. The plurality of light-emitting components 20 are arranged in a matrix and are electrically connected to one side of the array substrate 10. The driver chip 30 is electrically connected to another side of the array substrate 10. Specifically, the light-emitting component 20 is electrically connected to a displaying side of the array substrate 10. The driver chip 30 is electrically connected to a non-displaying side of the array substrate 10.

The array substrate 10 comprises a transparent substrate 11, a thin film transistor (TFT) layer 12 (hereinafter referred to as a TFT layer), a passivation layer 13, a pixel electrode layer 14, and a fanout circuit 15. The transparent substrate 11 has a first surface 11a and a second surface 11b disposed opposite to the first surface 11a. The TFT layer 12 is disposed on the first surface 11a of the transparent substrate 11. The passivation layer 13 and the pixel electrode layer 14 are sequentially stacked on the TFT layer 12. The fanout circuit 15 are disposed on the second surface 11b of the transparent substrate 11. The fanout circuit 15 is used to electrically connected the TFT layer 12 and the driver chip 30.

A plurality of openings 101 are provided on the array substrate 10. The plurality of openings 101 are located on edges of the array substrate 10 and penetrating the array substrate 10. The array substrate 10 comprises a plurality of electrical connection parts 16. Each electrical connection part 16 is disposed in one opening 101. The electrical connection part 16 is used to electrically connect the TFT layer 12 and the fanout circuit 15.

Specifically, the transparent substrate 11 is used to support other elements of the array substrate 10. For example, the transparent substrate 11 could be a plastic substrate or a glass substrate. In one embodiment of the present disclosure, the base substrate 10 could be a flexible substrate, for example, a polyimide substrate.

The TFT layer 12 comprises a plurality of thin film transistors (TFTs) used for displaying. The TFT layer 12 comprises a channel light-shielding layer 121, a buffer layer 122, a semiconductor layer 123, a gate insulating layer 124, a gate metal layer 125, an interlayer insulating layer 126, and a source drain metal layer 127 stacked on the transparent substrate 11.

The channel light-shielding layer 121 is disposed on a first surface 11a of the transparent substrate 11. The channel light-shielding layer 1211 is used for light-shielding a channel. The channel light-shielding layer 121 could be a metal with light-shielding function, such as molybdenum (Mo), silver (Ag), aluminum (Al), molybdenum-copper (MoCu) alloy, a stack of molybdenum (Mo) and aluminum (Al), etc.

The buffer layer 122 covers the channel light-shielding layer 121 and the transparent substrate 11. The buffer layer 122 is used to prevent metals of the channel light-shielding layer 121 from diffusing into the semiconductor layer 123. The buffer layer 122 could be SiNx, SiOx, a stack of SiNx and SiOx, or a stack of AlOx and SiOx, etc.

The semiconductor layer 123 is disposed on the buffer layer 122. The semiconductor layer 123 is disposed corresponding to the channel light-shielding layer 121. The semiconductor layer 123 is a channel layer of the TFT. Oxide semiconductor materials, such as, indium zinc oxide (IZO), gallium indium oxide (IGO), indium gallium zinc oxide (IGZO), indium gallium tin oxide (IGTO), indium gallium zinc tin oxide (IGZTO), etc., can be applied as the semiconductor layer 123. Amorphous silicon, monocrystalline silicon, low-temperature polycrystalline silicon, etc., can also be applied as the semiconductor layer 123.

The gate insulating layer 124 covers the semiconductor layer 123 and the buffer layer 122. SiNx, SiOx, AlOx, a stack of SiNx and SiOx, or a stack of AlOx and SiOx, etc., can be applied as the gate insulating layer 124.

The gate metal layer 125 is disposed on the gate insulating layer 124. The gate metal layer 125 comprises a plurality of gate electrodes 125G and a plurality of gate lines 125GL connected to the plurality of gate electrodes 125G. The plurality of gate electrodes 125G are disposed on the semiconductor layer 123. The plurality of gate lines 125GL are arranged in a first direction X in top view. A material of the gate metal layer 125 could be tantalum (Ta), tungsten (W), molybdenum (Mo), aluminum (Al), titanium (Ti), copper-niobium (CuNb) alloy, etc., or a stack of copper (Cu) and molybdenum (Mo), a stack of copper (Cu) and molybdenum-titanium (MoTi) alloy, a stack of copper (Cu) and titanium (Ti), a stack of aluminum (Al) and molybdenum (Mo), and a stack of molybdenum (Mo) and tantalum (Ta), a stack of molybdenum (Mo) and tungsten (W), a stack of molybdenum (Mo)-aluminum (Al)-molybdenum (Mo), etc.

The interlayer insulating layer 126 covers the buffer layer 122, the semiconductor layer 123 and the gate metal layer 125. For example, SiOx, a stack of SiNx and SiOx, etc., can be applied as the interlayer insulating layer 126.

The source drain metal layer 127 is disposed on the interlayer insulating layer 126. The source drain metal layer 127 comprises a plurality of source electrodes 127S, a plurality of drain electrodes 127D, and a plurality of source/drain lines 127L connected to the plurality of source electrodes 127S and the plurality of drain electrodes 127D. The source electrode 127S and the drain electrode 127D are located at two opposite ends of the semiconductor layer 123. The source electrode 127S and the drain electrode 127D are connected with the semiconductor layer 123 by through holes formed in the interlayer insulating layer 126, respectively. The gate electrode 125G and the gate insulating layer 124 are located between the source electrode 127S and the drain electrode 127D. When the TFT is turned on, current flows in the semiconductor layer 123 between the source electrode 127S and the drain electrode 127D. A plurality of source/drain lines 127L are arranged in a second direction Y. In one embodiment of the present disclosure, the first direction X and the second direction Y are perpendicular. The same material as the gate metal layer 125 can be applied as the source drain metal layer 127, for example, a stack of copper (Cu) and molybdenum (Mo), a stack of copper (Cu) and molybdenum-titanium (MoTi) alloy, a stack of copper (Cu) and titanium (Ti), a stack of aluminum (Al) and molybdenum (Mo), and copper-niobium (CuNb) alloy, etc.

The passivation layer 13 is disposed on the TFT layer 12 to flatten a surface of the thin film transistor layer 12. The same material as the above-mentioned insulating layers can be used as the passivation layer 13. For example, SiOx, a stack of SiNx and SiOx, etc.

The light-emitting electrode layer 14 is disposed on the passivation layer 13, and the light-emitting electrode layer 14 comprises a plurality of pixel electrodes 141, and a plurality of common electrodes 142. The pixel electrode 141 and the common electrode 142 are used to power the light-emitting component 20 so as to control the light-emitting of the light-emitting component 20. The pixel electrode 141 can be connected to one of the source electrode 127S and the drain electrode 127D. The common electrode 142 is provided with a common voltage.

The fanout circuit 15 are disposed on a second surface 11b of the transparent substrate 10 and are located on edges of the array substrate 10. The fanout circuit 15 comprises a metal circuit layer 151, a transparent circuit layer 153, and a circuit insulating layer 152 disposed between the metal circuit layer 151 and the transparent circuit layer 153. A material of the metal circuit layer 151 can be a stack of molybdenum (Mo) and copper (Cu), or a stack of molybdenum-titanium (MoTi) alloy and Copper (Cu). A material of the transparent circuit layer 153 is ITO or IZO.

In one embodiment of the present disclosure, the plurality of openings 101 are a plurality of recesses provided on a sidewall 10a of the array substrate 10. The plurality of openings 101 comprises a plurality of first openings 101a arranged in a first direction X and a plurality of second openings 101b arranged in a second direction. A plurality of electrical connection parts 16 comprise a plurality of first electrical connection parts 16a each disposed in the first opening 101a and a plurality of second electrical connection parts 16b each disposed in the second opening 101b. The first electrical connection part 16a is electrically connected to the gate line 125GL, the second electrical connection part 16b is electrically connected to the source/drain line 127L. The gate line 125GL is electrically connected to the fanout circuit 15 via the first electrical connection part 16a, and finally electrically connected to the driver chip 30. The source/drain line 127L is electrically connected to the fanout circuit 15 via the second electrical connection part 16b, and finally electrically connected to the source driver chip. The electrical connection part consists of a conductive material. In one embodiment of the present disclosure, the electrical connection part 16 can be a patterned metal trace.

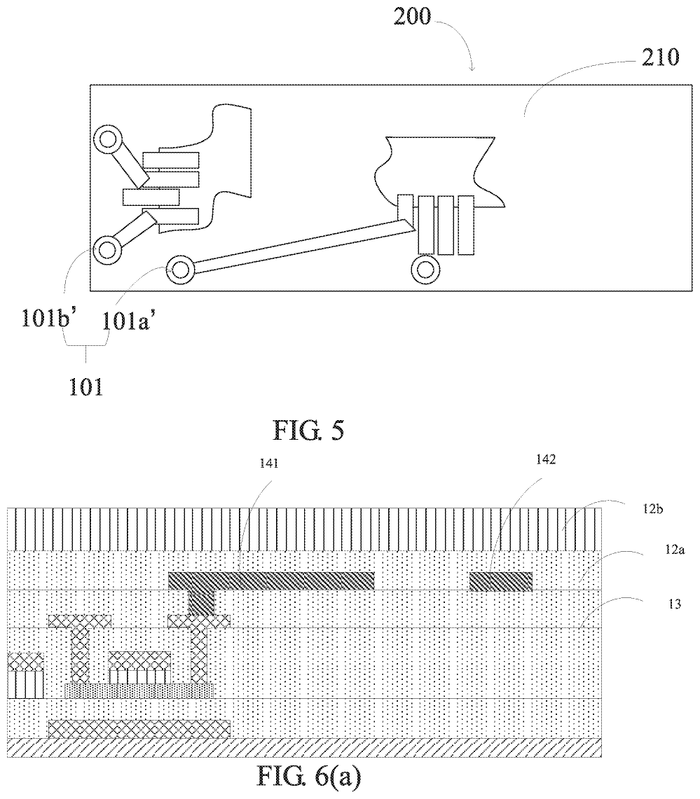

Please refer to FIG. 5, in a display panel 200 according to another embodiment of the present disclosure, the plurality of openings 101′ are defined as a plurality of through-holes provided in the array substrate 210, and comprises a plurality of first openings 101a′ arranged in a first direction X and a plurality of second openings 101b′ arranged in a second direction.

In other embodiments of the present disclosure, the display panel can only comprise the first opening 10a and the first electrical connection part 16a described in above embodiments, or can only comprises the second opening 101b and the second electrical connection part 16b. One of the gate line 125GL and the source line 127SL is electrically connected to the driver chip 30 through the electrical connection part 16, and the other one is electrically connected to the driver chip 30 in other way.

In this embodiment, the first electrical connection part 16a comprises a first electrical connection convex 16a1. The second electrical connection part 16b comprises a second electrical connection convex 16b1. A plurality of recesses are provided on the sidewall 10a of the array substrate 10 inside the plurality of openings 11. The gate line 125GL is exposed by the recess 10a1 and contacts with the first electrical connection convex 16a1. The source/drain line 127L is exposed by the recess 10a1 and contacts with the second electrical connection convex 16b1.

In one embodiment of the present disclosure, the display panel 100 is a micro light-emitting diode (Micro LED) type display panel. The light-emitting component 20 is a light-emitting element of a micro light-emitting diode. The light-emitting component 20 comprises a first electrode 21, a second electrode 22, a pixel definition layer, and a micro light-emitting diode, a protection layer, etc., which are located in the pixel definition layer. The first electrode 21 and the second electrode 22 are respectively connected to the pixel electrode 141 and the common electrode 142. In one embodiment of the present disclosure, the electric potential of the pixel electrode 141 is positive. The pixel electrode 141 is electrically connected to the drain electrode 127D through a through hole formed in the passivation layer. In other embodiments of the present disclosure, the electric potential of the pixel electrode 141 is negative. The pixel electrode 141 is electrically connected to the source electrode 127S through a through hole formed in the passivation layer. According to differences in structures, micro light-emitting diode can be divided into vertically structural micro light-emitting diodes and horizontally structural micro light-emitting diodes. The first electrode 21 and the second electrode 22 of the vertically structural micro light-emitting diode are located at an upper side and a lower side of the micro light-emitting diode, respectively. The first electrode 21 and the second electrode 22 of the horizontally structural micro light-emitting diode are both located at a lower side of the micro light-emitting diode. In the present embodiment, the micro light-emitting diode 20 is horizontally structural.

The driver chip 30 is disposed on the second surface 11b of the transparent substrate 11 and is electrically connected to the fanout circuit 15. The driver chip 30 can be in the form of chip on film (COF), that is, the driver chip 30 is disposed on the film and connected to the fanout circuit 15. The driver chip 30 can comprise a gate driver chip and a source/drain driver chip. The gate driver chip is connected to the gate lines 125GL. The source/drain driver chip is electrically connected to the source/drain lines 127L. The fanout circuit 15 and the driver chip 30 of the display panel 100 of the present disclosure are disposed at a backside of the array substrate 10. By providing the openings 101 on the edge of the array substrate 10 and forming the electrical connection parts 16 in the openings 101 to electrically connect the driver chip 30, the fanout circuit 16, and the TFT layer 12, a display area becomes closer to a bezel area, so as to achieve an effect of bezel-free or narrow-bezel.

In other embodiments of the present disclosure, the array substrate can also comprise a common electrode line, a power supply and voltage line, and other signal lines used to transmit signals, and the driver chip can also comprise a power supply chip and other driver chips. Similarly, by providing the openings on the edges of the array substrate and forming the electrical connection parts in the openings to electrically connect the driver chip, the fanout circuit, and the plurality of signal lines, a display area becomes closer to a bezel area, so as to achieve an effect of bezel-free or narrow-bezel.

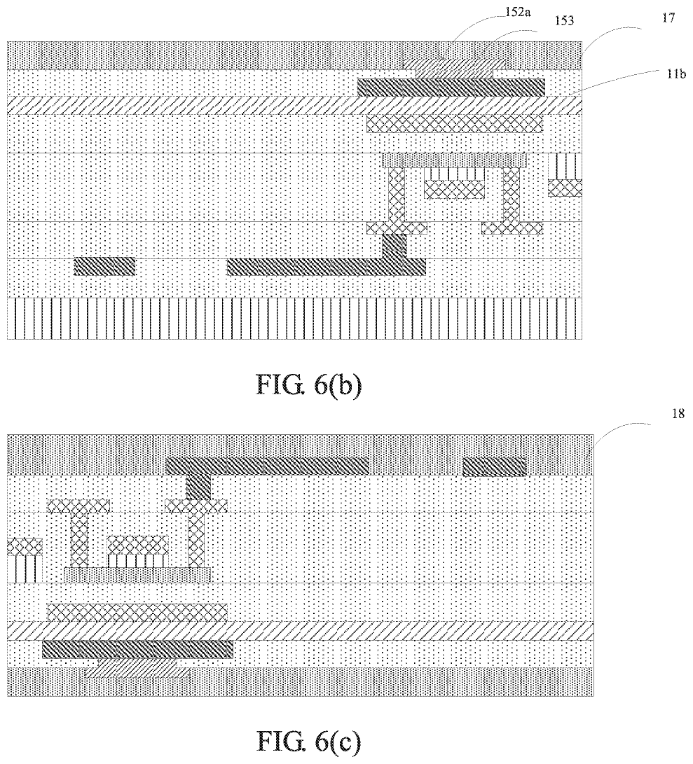

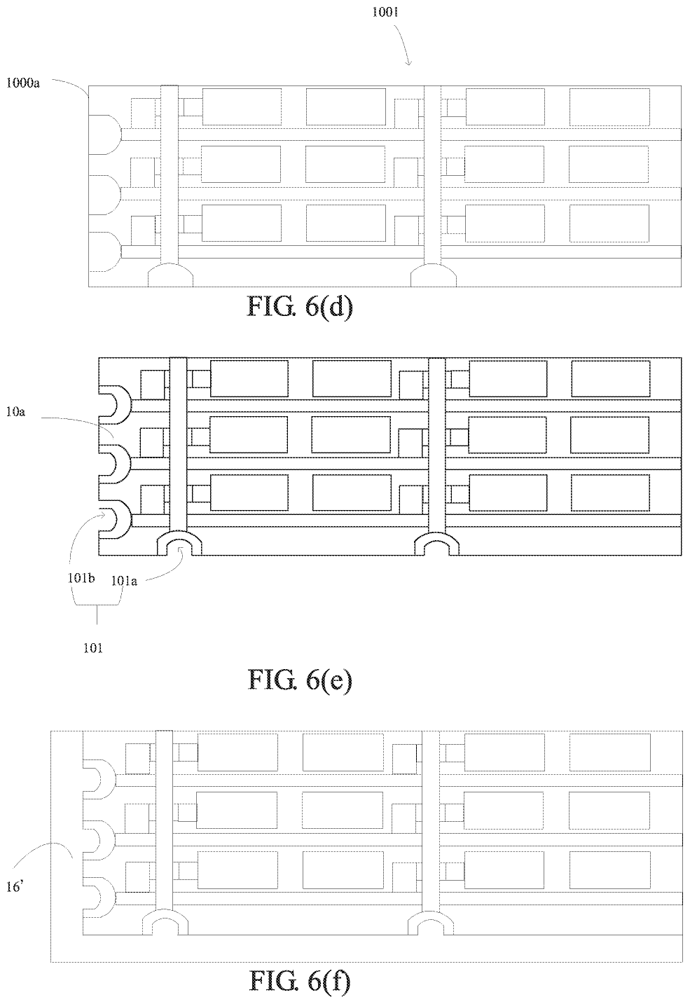

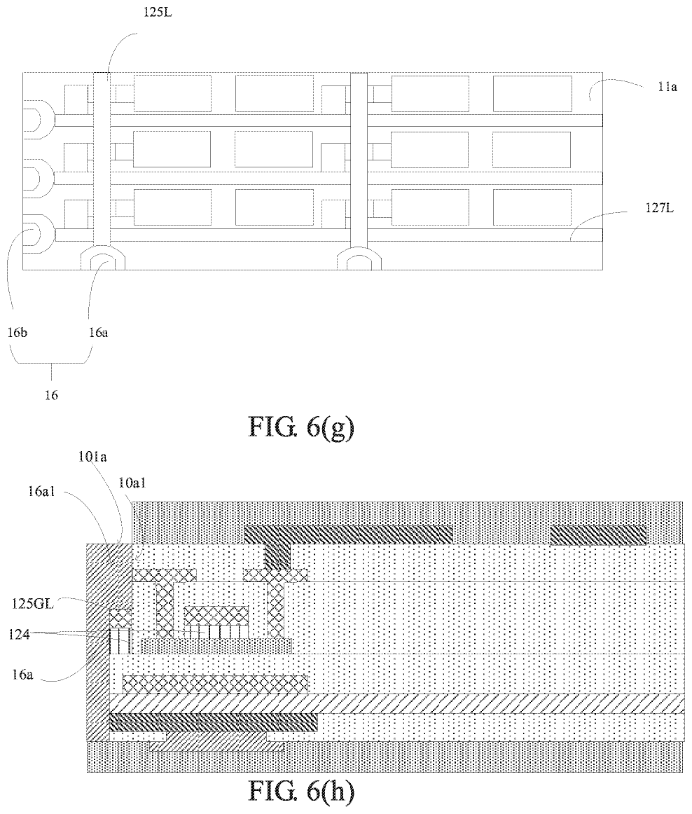

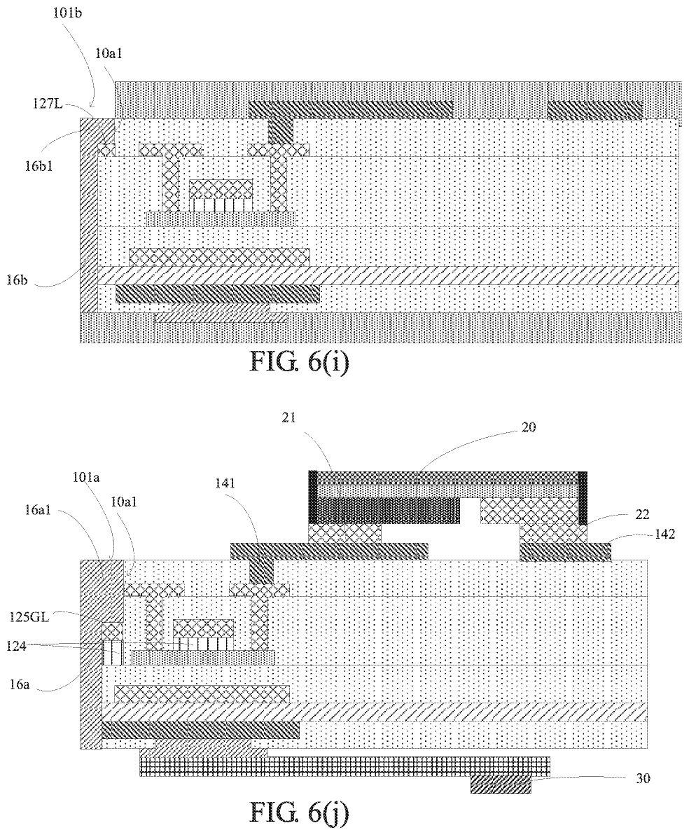

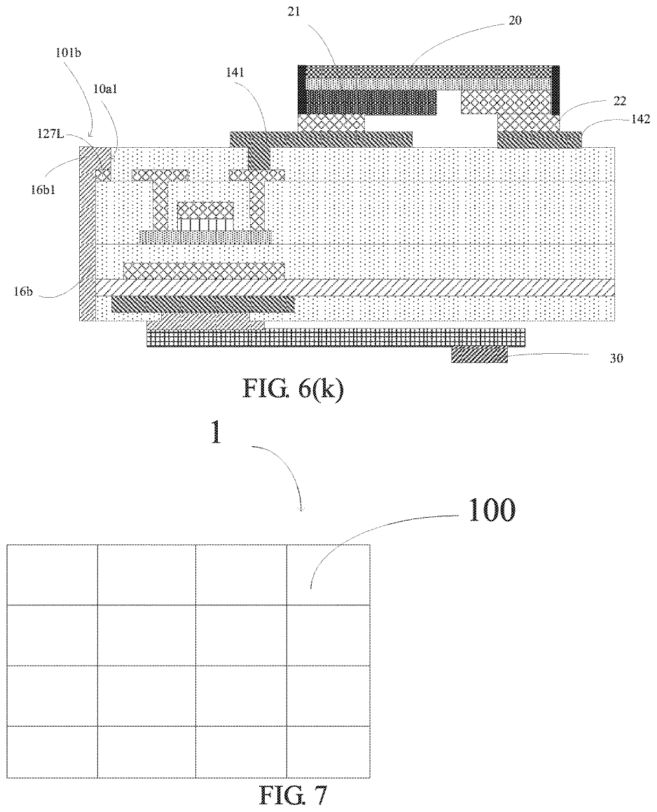

Please refer to FIG. 6(a) to FIG. 6(j), a manufacturing method of a display panel 100 is provided by one embodiment of the present disclosure, comprising the steps of:

A fanout circuit forming step of providing a first substrate 1000, wherein the first substrate 1000 comprises a transparent substrate 11, a TFT layer 12, a passivation layer 13, and a pixel electrode layer 14. The transparent substrate 11 comprises a first surface 11a and a second surface 11b disposed opposite to the first surface 11a, the TFT layer 12 is disposed on the first surface 11a of the transparent substrate 11, and forming a fanout circuit 15 on the second surface 11b to obtain a base substrate 1001.

An opening forming step of providing a plurality of openings 101 on edges of the base substrate 1001,

wherein the plurality of openings 101 are penetrating the middle substrate, a first end of the opening 101 connects with the fanout circuit 15, and a second end connects with the TFT layer 12. In one embodiment of the present disclosure, the opening 101 is located at a position where an orthographic projection of the fanout circuit 15 overlaps an orthographic projection of the TFT layer 12.

An electrical connection part forming step of forming an electrical connection part 16 in the opening 101, the electrical connection part 16 is electrically connected between the TFT layer 12 and the fanout circuit 15, and an array substrate 10 is obtained;

a bonding step of bonding a driver chip 30 on the fanout circuit 15; and

Aa light-emitting component forming step of electrically connecting a plurality of light-emitting components 20 on the array substrate 10.

Please refer to FIG. 6(a) to FIG. 6(c), in the fanout circuit forming step, the TFT layer 12 comprises a channel light-shielding layer 121, a buffer layer 122, a semiconductor layer 123, a gate insulating layer 124, a gate metal layer 125, an interlayer insulating layer 126, and a source drain metal layer 127 stacked on the transparent substrate 11. The gate metal layer 125 comprises a plurality of gate electrodes 125G and a plurality of gate lines 125GL. The source drain metal layer 127 comprises a plurality of source electrodes 127S, a plurality of drain electrodes 127D, and a plurality of source/drain lines 127L.

A first protective layer 12a and a second protective layer 12b are disposed on the pixel electrode layer 14. The first protective layer 12a and the second protective layer 12b are used to protect the pixel electrode layer 14 when the first substrate 1000 is inverted to form the fanout circuit 15. The step of forming the fanout circuit 15 on the second surface 11b comprises step of inverting the first substrate 1000 to make the second surface 11b face upward. A metal circuit layer 152 and a circuit insulating layer 152 is subsequently formed on the second surface 11b. For example, the metal circuit layer 151 can be formed by depositing and patterning a film of fanout circuit metal. And a circuit insulating film 152 is deposited on the metal circuit layer 151.

A through-hole 152a is provided on the circuit insulating film 152 and a transparent circuit layer 153 is formed. For example, the transparent circuit layer 153 is formed by depositing a transparent conductive layer in the through-hole 152a and patterning the transparent conductive layer. The metal circuit layer 151 is electrically connected with the transparent circuit layer 153 to form the fanout circuit 15.

Besides, the base substrate 1001 can further comprises a first organic protective layer 17 covering the fanout circuit 15 to protect the fanout circuit 15. The first organic protective layer 17 can be formed by depositing and etching a etch stopper layer.

Here, the substrate is inverted to make the first surface 11a face upward. The first protective layer 12a and the second protective layer 12b are removed, and a second organic protective layer 18 is formed on the pixel electrode layer 14. The second organic protective layer 18 can be formed by depositing and etching a etch stopper layer. Thus, a base substrate 1001 protected by the first organic protective layer 17 and the second organic protective layer 18 is obtained.

Please refer to FIG. 6(a) to FIG. 6(e), FIG. 6(a) to FIG. 6(e) is the top view of the opening forming step. In the opening forming step, the step of providing a plurality of openings on edges of the base substrate 1001 comprises a step of forming a plurality of recesses on a sidewall 1000a of the base substrate 1001. Specifically, the plurality of recesses are formed on the base substrate 1011 by means of laser drilling or mechanical drilling. The plurality of openings 101 comprise a plurality of first openings 101a arranged in a first direction X and a plurality of second openings 101b arranged in a second direction Y.

Please refer to FIG. 6(f) to FIG. 6(i), wherein FIG. 6(f) to FIG. 6(g) is the top view of the electrical connection part forming step, and FIG. 6(h) to FIG. 6(i) is the cross-sectional view of the electrical connection part forming step along the A-A line and the B-B line. The electrical connection part forming step comprises the steps of:

etching the sidewall 10a inside the openings 101 to expose the gate lines 125GL and the source/drain lines 127L.

Specifically, etching the sidewall 10a inside the first openings 101a until the gate metal layer 125 to form a recess 10a1 for exposing the gate lines 125GL. Etching the sidewall 10a inside the second openings 101b until the source drain metal layer 127 to form a recess 10a1 for exposing the source/drain lines 127L. Chemical etching can be applied as means of etching.

A metal layer 16′ is formed in the opening 101 to form the electrical connection part 16. Method of forming the metal layer 16′ can be film coating means. The metal layer 16′ outside the groove is removed by means of grinding (for example) and only the metal layer 16′ inside the grooves is retained, so that the metal layer 16′ is patterned into a metal trace to form an electrical connection part 16. Specifically, the first electrical connection part 16a comprises a first electrical connection convex 16a1. The second electrical connection part 16b comprises a second electrical connection convex 16b1. The gate line 125GL contacts with the first electrical connection convex 16a1. The source/drain line 127L contacts with the second electrical connection convex 16b1.

In other embodiments of the present disclosure, the electrical connection part forming step can be completed by printing a metal trace directly in the sidewall 10a inside the openings 101, forming the metal layer inside the openings, and then making the metal trace by laser sintering or by means of Damascus method.

Herein, please refer to FIG. 5, in a display panel 200 according to another embodiment of the present disclosure, the openings 101′ (including a first opening 101a′ and a second opening 101b′ are defined as through-holes provided in an array substrate 210. Herein, an electrical connection part is formed by filling metal into the through-hole.

Please refer to FIG. 6 (j) and FIG. 6 (k) at the same time, the bonding step comprises the following steps of removing the first organic protective layer 17 and bonding the drive chip 30 on the fanout circuit 15.

The light-emitting component forming step comprises the following steps of removing the second organic protective layer 18, electrically connecting the first electrode 21 of the light-emitting component 20 on the pixel electrode 141, and electrically connecting the second electrode 22 of the light-emitting component 20 on the common electrode 142.

Thus, the display panel 100 provided by the first embodiment of this disclosure is obtained.

In other embodiments of the present disclosure, the array substrate can also comprise a common electrode line, a power supply and voltage line, and other signal lines used to transmit signals, and the driver chip can also comprise a power supply chip and other driver chips. Similarly, by the same method of providing the openings on the edges of the array substrate and forming the electrical connection parts in the openings to electrically connect the driver chip, the fanout circuit and the signal lines, a display area becomes closer to a bezel area, so as to achieve an effect of bezel-free or narrow-bezel.

A tiled display panel 1 according to a third embodiment of the present disclosure comprises a plurality of display panel 100 tightly arranged in a matrix. The plurality of display panel 100 is bezel-free or narrow-bezel panel, therefore, there is no apparent seams in the tiled display panel 100.

The above-mentioned bezel-free display panel or narrow-bezel display panel 100 are applied in a tiled display panel 1 according to the third embodiment of the present disclosure, so that seams can be narrowed to a size of one-pixel unit, so as to make the seams difficult to be recognized by the naked eye by users and achieve an effect of eliminating or reducing seams.

The above-mentioned embodiments only list micro LED type display panels, but it can be understood that the application can also be used in other active light-emitting type display panels. For example, the application can be used in organic light-emitting diode (OLED) display panels. That is to say, an organic light-emitting component is applied as the light-emitting component. Herein, the pixel electrode is defined as an anode of the organic light-emitting component. The application can also be used in passive light-emitting display panels, such as LCD panels.

The above description provides a detailed introduction to the application. In this disclosure, specific examples are applied to explain principle and embodiments of the application. The description of the above embodiments is only used to help understand the application. At the same time, for those skilled in the art, according to the thought of the present disclosure, there will be changes in the specific embodiments and application scope. In conclusion, the content of the specification should not be understood as the limitation of the application.

1. A display panel, comprising a plurality of light-emitting components, an array substrate, and a driver chip, wherein the plurality of light-emitting components are electrically connected to a side of the array substrate, and the driver chip is electrically connected to another side of the array substrate, and
the array substrate comprises:
a base substrate comprising a first surface and a second surface disposed opposite to the first surface;
a plurality of signal lines disposed on the first surface of the base substrate; and
a fanout circuit disposed on the second surface of the base substrate and electrically connected to the plurality of signal lines;
wherein the driver chip is disposed on the second surface of the base substrate and electrically connected to the fanout circuit; and
a plurality of openings are provided on the array substrate, wherein the plurality of openings are located on an edge of the array substrate and penetrate the array substrate, the array substrate comprises a plurality of electrical connection parts, and the plurality of electrical connection parts are electrically connected to the plurality of signal lines and the fanout circuit.

2. The display panel of claim 1, wherein the openings are defined as grooves provided on a sidewall of the array substrate.

3. The display panel of claim 1, wherein the openings are defined as through-holes penetrating the array substrate.

4. The display panel of claim 1, wherein a recess is provided on a sidewall of the array substrate inside the openings, the electrical connection parts comprise an electrical connection convex, the signal lines are exposed by the recess, and the electrical connection convex contacts the signal lines.

5. The display panel of claim 1, wherein the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, and each of the first electrical connection parts is electrically connected to one of the gate lines.

6. The display panel of claim 1, wherein the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

7. The display panel of claim 1, wherein the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, each of the first electrical connection parts is electrically connected to one of the gate lines, the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

8. The display panel of claim 1, wherein the light-emitting components are defined as a micro light-emitting diode or an organic light-emitting component.

9. A manufacturing method of a display panel, comprising steps of:
a fanout circuit forming step of providing a first substrate, wherein the first substrate comprises a base substrate and a plurality of signal lines, the base substrate comprises a first surface and a second surface disposed opposite to the first surface, the plurality of signal lines are disposed on the first surface of the base substrate, and the fanout circuit is formed on the second surface;
an opening forming step of providing a plurality of openings on an edge of the base substrate, wherein the plurality of openings penetrate the middle first substrate, first end connects with the fanout circuit, and second end connects with the signal lines;
an electrical connection part forming step of forming the electrical connection part in the openings, the electrical connection part is electrically connected to the signal lines the fanout circuit, and the array substrate is obtained;
a bonding step of bonding a driver chip on the fanout circuit; and
a light-emitting component forming step of electrically connecting a plurality of light-emitting components on the array substrate.

10. The manufacturing method of the display panel of claim 9, wherein the step of providing the plurality of openings on the edge of the base substrate comprises a step of forming a plurality of recesses on a sidewall of the base substrate or providing the plurality of openings in the base substrate.

11. The manufacturing method of the display panel of claim 9, wherein
the electrical connection part forming step comprises the steps of:
etching a sidewall inside the opening to expose the signal lines,
and forming a metal layer in the openings to form the electrical connection part.

12. A tiled display panel formed by tiling a plurality of display panels,
wherein the display panel comprises a plurality of light-emitting components, an array substrate, and a driver chip, wherein the plurality of light-emitting components are electrically connected to a side of the array substrate, and the driver chip is electrically connected to another side of the array substrate, and
the array substrate comprises:
a transparent substrate comprising a first surface and a second surface disposed opposite to the first surface;
a plurality of signal lines disposed on the first surface of the base substrate; and
a fanout circuit disposed on the second surface of the base substrate and electrically connected to the plurality of signal lines;
wherein the driver chip disposed on the second surface of the base substrate and electrically connected to the fanout circuit; and
a plurality of openings are provided on the array substrate, wherein the plurality of openings are located on an edge of the array substrate and penetrate the array substrate, the array substrate comprises a plurality of electrical connection parts, and the plurality of electrical connection parts are electrically connected to the plurality of signal lines and the fanout circuit.

13. The tiled display panel of claim 12, wherein the openings are defined as grooves provided on a sidewall of the array substrate.

14. The tiled display panel of claim 12, wherein the openings are defined as through-holes penetrating the array substrate.

15. The tiled display panel of claim 12, wherein a recess is provided on a sidewall of the array substrate inside the openings, the electrical connection parts comprise an electrical connection convex, the signal lines are exposed by the recess, and the electrical connection convex contacts the signal lines.

16. The tiled display panel of claim 12, wherein the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, and each of the first electrical connection parts is electrically connected to one of the gate lines.

17. The tiled display panel of claim 12, wherein the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

18. The tiled display panel of claim 12, wherein the plurality of openings comprise a plurality of first openings arranged in a first direction, the plurality of electrical connection parts comprise a plurality of first electrical connection parts disposed in the plurality of first openings, the plurality of signal lines comprise a plurality of gate lines, each of the first electrical connection parts is electrically connected to one of the gate lines, the plurality of openings comprise a plurality of second openings arranged in a second direction, the plurality of electrical connection parts comprise a plurality of second electrical connection parts disposed in the plurality of second openings, the plurality of signal lines comprise a plurality of source/drain lines, and each of the second electrical connection parts is electrically connected to one of the source/drain lines.

19. The tiled display panel of claim 12, wherein the light-emitting components are defined as a micro light-emitting diode or an organic light-emitting diode.
